(19) United States
(12) Patent Application Publication
(10) Pub. No.: US 2004/0149332 A1
(43) Pub. Date: Aug. 5, 2004

(54) Solar cell and fabrication method thereof, interconnector for solar cell, solar cell string, and solar cell module

(75) Inventors: Satoshi Tanaka, Yamatotakada-shi (JP); Masaomi Hioki, Gose-shi (JP)

Correspondence Address: NIXON & VANDERHYE, PC, 1100 N GLEBE ROAD, 8TH FLOOR, ARLINGTON, VA, 22201-4714, US

(73) Assignee: SHARP KABUSHIKI KAISHA, Osaka (JP)

(21) Appl. No.: 10/670,195

(22) Filed: Sep. 26, 2003

(30) Foreign Application Priority Data
Oct. 4, 2002 (JP) 2002-292683(P)
Jul. 29, 2003 (JP) 2003-203217(P)

(51) Int. Cl. H01L 31/00

(52) U.S. Cl. 136/256

(57) ABSTRACT

A solar cell has silver paste electrodes coated with a lead-free solder layer. The silver paste electrodes are formed by firing silver paste. The average grain size of powdery glass included in the silver paste is at least 11 μm, or the amount of powdery glass included in the silver paste is 2.8 to 10.0 mass %, or the average thickness of the silver paste electrode is at least 15 μm. Thus, a solar cell further improved in reliability, maintaining adherence between the silver paste electrode and an n type diffusion layer or p type silicon substrate, suppressed in detachment of an interconnector, and a fabrication method of such a solar cell are provided.

### BACKGROUND OF THE INVENTION

1. Field of the Invention

The present invention relates to a solar cell, particularly a solar cell having a silver paste electrode coated with lead-free solder, a fabrication method of such a solar cell, an interconnector for such solar cells, a solar cell string, and a solar cell module.

2. Description of the Related Art

A schematic sectional view of a conventional solar cell in a solder coating process is shown in FIG. 4. An n type diffusion layer 2 is formed at one side, identified as the light receiving side, of a p type silicon substrate 1 subjected to etching. A major part of the region of n type diffusion layer 2 is covered with an anti-reflection film 3 directed to reduce the surface reflectance. Also, a back surface aluminum electrode 4 is formed covering the major region at the back side of p type silicon substrate 1. Silver paste electrodes 5 and 6 are formed at a partial region at the light receiving side of n type diffusion layer 2 and a partial region at the back side of p type silicon substrate 1, respectively. Each of silver paste electrodes 5 and 6 is coated with a solder layer 8.

Such a solar cell is fabricated by the processing steps shown in FIG. 3. Specifically, in the case where crystalline silicon is employed, p type silicon substrate 1 is first subjected to etching. Following this substrate etching step, an n type diffusion layer formation step is conducted to form an n type diffusion layer 2 at the light receiving side of p type silicon substrate 1 subjected to etching. Then, an anti-reflection film formation step of forming an anti-reflection film 3 directed to reduce the surface reflectance is conducted.

The back surface of p type silicon substrate 1 is subjected to screen-printing, whereby substantially the entire surface (excluding the region where a silver paste electrode is to be formed at the back surface at a subsequent step) is printed with aluminum paste. The aluminum paste is dried and fired in an oxidizing atmosphere at high temperature to form a back surface aluminum electrode 4. This processing stage corresponds to the back surface aluminum paste printing, drying, and firing step.

Also, a partial region of the light receiving side of anti-reflection film 3 and a partial region at the back side of p type silicon substrate 1 have a pattern of silver paste printed through screen-printing. The silver paste is fired in an oxidizing atmosphere at high temperature to form respective silver paste electrodes 5 and 6. Specifically, a back surface silver paste printing and drying step is conducted, followed by firing to form silver paste 10 electrode 6. Also, a light receiving side silver paste printing and drying step is conducted, followed by firing to form silver paste electrode 5. At this stage, the printed and dried silver paste on anti-reflection film 3 at the light receiving side has the silver paste constituent transmitted through anti-reflection film 3 so as to reach as far as n type diffusion layer 2 by the firing process. Therefore, silver paste electrode 5 will be formed on n type diffusion layer 2 as shown in FIG. 4. In the case where silver paste electrode 5 and silver paste electrode 6 are to be formed at the same time, a simultaneous firing step of firing the printed and dried silver paste at both the light receiving side and back side at the same time is allowed. Then, the solar cell device formed as described above is immersed in an activator-containing flux at normal temperature for several ten seconds.

Following this flux immersing step, the solar cell device is exposed to hot air to be dried. Then, the solar cell device is immersed in a 6:4 eutectic solder bath containing 2 mass % silver at approximately 195° C. for approximately one minute to have a coat of solder layer 8 applied on silver plate electrodes 5 and 6.

Following this coating step of solder layer 8, the solar cell device is ultrasonically washed several times in water of ordinary temperature or hot water, then rinsed with pure water, and exposed to hot air to be dried. Thus, a solar cell is fabricated through the above-described steps.

A solar cell is interconnected with an interconnector to form a string, as shown in FIG. 5. Specifically, referring to the conventional string of FIG. 5, a main electrode 21 coated with 6:4 eutectic solder is formed at a solar cell 10. A plurality of solar cells 10 are connected by an interconnector 22 coated with 6:4 eutectic solder. Such a string was fabricated as set forth below. Interconnector 22 identified as a copper core line coated with 6:4: eutectic solder is superimposed on main electrode 21 coated with 6:4 eutectic solder of solar cell 10, and then exposed to a blow of hot air at approximately 400° C. to melt the solder. The solder is then cooled to be solidified to establish attachment. This process is repeated for the plurality of solar cells on the front and back sides to produce a cell string. The string is used to fabricate a solar cell module.

From the standpoint of environmental apprehension nowadays, the ill effect of lead to the human body is of great concern. The trend is towards developing various devices absent of lead. The demand for fabricating a solar cell in a lead-free state, i.e., not containing lead, is great.

To meet such demands, a solar cell is proposed, forming a silver paste electrode by firing silver paste containing powdery silver, powdery glass, an organic vehicle, an organic solvent, phosphorus oxide, and halide, and having this silver paste electrode coated with Sn—Bi—Ag based or Sn—Ag based lead-free solder (refer to Japanese Patent Laying-Open No. 2002-217434).

A solar cell having a silver paste electrode coated with lead-free solder maintains adherence under the environment condition of a predetermined temperature and humidity. However, such a solar cell exhibits degradation in adherence between the silver paste electrode and the n type diffusion layer or p type silicon substrate under the environment condition of great change in temperature and/or humidity. There was a problem that the interconnector connecting the solar cells is detached.

### SUMMARY OF THE INVENTION

In view of the foregoing, an object of the present invention is to provide a solar cell further improved in reliability, maintaining adherence between a silver paste electrode and an n type diffusion layer or p type silicon substrate, and having detachment of an interconnector suppressed, and a fabrication method of such a solar cell.

Another object of the present invention is to provide an interconnector having a metal core line coated with lead-free solder, and connected to the silver paste electrode of the above solar cell with lead-free solder.

A further object of the present invention is to provide a solar cell string and module of high reliability, having the above solar cells connected with the above interconnector.

According to an aspect of the present invention, a solar cell has a silver paste electrode coated with lead-free solder, characterized in that the silver paste electrode is formed by firing silver paste, and the average grain size of powdery glass included in the silver paste is 11 μm at most.

According to another aspect of the present invention, a solar cell has a silver paste electrode coated with lead-free solder, characterized in that the silver paste electrode is formed by firing silver paste, and the amount of powdery glass contained in the silver paste is 2.8 to 10.0 mass %.

According to a further aspect of the present invention, a solar cell has a silver paste electrode coated with lead-free solder, characterized in that the average thickness of the silver paste electrode after firing is at least 15 μm.

According to still another aspect of the present invention, a fabrication method of a solar cell including the steps of printing silver paste at a partial region at a light receiving side of an anti-reflection film and at a partial region at a back side of a p type silicon substrate, firing the silver paste to form a silver paste electrode, and coating the silver paste electrode with lead-free solder is characterized in that powdery glass included in the silver paste is sifted through a sieve having an opening diameter of 73 μm at most (at least 250 mesh).

According to a still further aspect of the present invention, a fabrication method of a solar cell including the steps of printing silver paste at a partial region at a light receiving side of an anti-reflection film and at a partial region at a back side of a p type silicon substrate, firing the silver paste to form a silver paste electrode, and coating the silver paste electrode with lead-free solder is characterized in that, in printing the silver paste, silver paste is applied at least two times by printing.

According to yet a further aspect of the present invention, a fabrication method of a solar cell including the steps of printing silver paste at a partial region at a light receiving side of an anti-reflection film and at a partial region at a back side of a p type silicon substrate, firing the silver paste to form a silver paste electrode, and coating the silver paste electrode with lead-free solder is characterized in that a mask having a thickness of three times the wire diameter is used in printing the silver paste.

According to yet another aspect of the present invention, an interconnector for a solar cell is coated with lead-free solder, and characterized in that the interconnector is connected to the silver paste electrode of the solar cell by lead-free solder.

According to yet a still further aspect of the present invention, a solar cell string is characterized in that a solar cell having the above silver paste electrode coated with lead-free solder is interconnected with the above interconnector for a solar cell.

According to an additional aspect of the present invention, a solar cell module has the above solar cell string incorporated.

In the solar cell of the present invention, detachment of the interconnector is suppressed, whereby the solar cell is improved in reliability. Accordingly, an interconnector for a solar cell connected to such solar cells of the present invention, a solar cell string having the above interconnector connected to such solar cells by lead-free solder, and a solar cell module incorporating such a string are also improved in reliability.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic sectional view of a solar cell according to the present invention.

FIG. 2 is a diagram to describe a solar cell string of the present invention.

FIG. 3 is a diagram to describe fabrication steps of a solar cell.

FIG. 4 is a schematic sectional view of a conventional solar cell.

FIG. 5 is a diagram to describe a conventional solar cell string.

### DESCRIPTION OF THE PREFERRED EMBODIMENTS

A solar cell according to an embodiment of the present invention has a silver paste electrode coated with lead-free solder, wherein the average grain size of powdery glass included in the silver paste is 11 μm at most. In the present specification, “average grain size” is the average grain size obtained by light scattering diffractometry. If the average grain size of powdery glass exceeds 11 μm, the interconnector detachment rate will become higher under an environmental condition of great change in temperature and/or humidity. The specific surface of powdery glass becomes larger as the average grain size of powdery glass becomes smaller, whereby the adherence in the silver paste and at the solar cell interface can be maintained. In view of the foregoing, the average grain size of powdery glass is preferably 8 μm at most, and more preferably 5 μm at most.

“Silver paste electrode” in the present specification refers to an electrode formed by applying silver paste through screen printing on both side surfaces of a solar cell, followed by drying and firing. Silver paste employed in fabricating such a silver paste electrode includes, as the main component, powdery silver, powdery glass, an organic vehicle, and an organic solvent, as well as material including illidium chloride and phosphorus oxide.

A solar cell according to another aspect of the present invention has a silver paste electrode coated with lead-free solder, wherein the amount of powdery glass contained in the silver paste is 2.8 to 10.0 mass %. If the amount of powdery glass is less than 2.8 mass %, the interconnector detachment rate under the environmental condition of great change in temperature and/or humidity will become higher. If the amount of powdery glass exceeds 10%, homogenous paste cannot be obtained, rendering difficult the printing process of a solar cell. In view of the foregoing, the amount of powdery glass contained in silver paste is preferably 2.8 to 7.0 mass %, further preferably 3.0 to 7.0 mass %, and most preferably 3.0 to 4.0 mass %.

A solar cell according to a further aspect of the present invention has a silver paste electrode coated with lead-free solder, wherein the average thickness of the silver paste electrode after firing is at least 15 μm. If the film thickness of the silver paste electrode after firing the silver paste is less than 15 μm, the strain stress imposed on the adhering interface between the n type diffusion layer or p type diffusion substrate and the silver paste electrode substance of the solar cell, generated by the difference in the coefficient of thermal expansion between the silicon substance of the solar cell and the silver paste electrode substance, can no longer be absorbed when the temperature and/or humidity changes greatly. This will lead to a higher interconnector detachment rate under the environmental condition of great change in temperature and/or humidity. In view of the foregoing, the film thickness of the silver paste electrode after the silver paste firing step is preferably at least 20 μm.

In the fabrication method of a solar cell of the present invention including the steps of printing silver paste at a partial region at a light receiving side of an anti-reflection film and at a partial region at a back side of a p type silicon substrate, firing the silver paste to form a silver paste electrode, and coating the silver paste electrode with lead-free solder, powdery glass sifted through a sieve in advance to reduce the average grain size of powdery glass contained in the silver paste can be employed. In addition to reducing the average grain size of powdery glass, the sifting process through a sieve is advantageous in that a particle size distribution containing more powdery glass of smaller grain size can be achieved by selectively removing powdery glass of large grain size. This contributes to maintaining adherence between the silver paste electrode and n type diffusion layer 2 or p type silicon substrate 1. In view of the foregoing, glass particles of large grain size can be removed sufficiently by using a sieve having an opening diameter of 73 μm at most (at least 250 mesh). From the above-described standpoint, a sieve is employed having an opening diameter of preferably 50 μm at most (at least 325 mesh), and further preferably 37 μm at most (at least 400 mesh).

According to another embodiment of a fabrication method of a solar cell of the present invention including the steps of printing silver paste at a partial region at a light receiving side of an anti-reflection film and at a partial region at a back side of a p type silicon substrate, firing the silver paste to form a silver paste electrode, and coating the silver paste electrode with lead-free solder, silver paste is applied at least two times in the silver paste screen-printing process to increase the thickness of the silver paste electrode formed by firing silver paste.

According to still another embodiment of a fabrication method of a solar cell of the present invention including the steps of printing silver paste at a partial region at a light receiving side of an anti-reflection film and at a partial region at a back side of a p type silicon substrate, firing the silver paste to form a silver paste electrode, and coating the silver paste electrode with lead-free solder, a mask having a thickness of three times the wire diameter can be employed in a silver paste screen-printing step in order to increase the thickness of the silver paste electrode formed by firing silver paste. In the present specification, a mask having a thickness of three times the wire diameter is a mesh woven mask composed of longitudinal wire (warp) and transverse wire (weft), wherein the thickness of the screen fabric is set to be three times the wire diameter by increasing the tension on one of the longitudinal wire and transverse wire. The mask is used to apply a thick paste in the printing process. For example, a mesh woven mask of stainless steel wire (produced by Nakanuma Art Screen Co. Ltd.) can be used.

The interconnector for a solar cell of the present invention is coated with lead-free solder, and connected to the above-described silver paste electrode of a solar cell by lead-free solder. Detachment from the solar cell can be suppressed by the interconnection with the silver paste electrode through that lead-free solder. The interconnector for connection with the solar cell can be fabricated by immersing a 2 mm wide and 0.2 mm thick copper line in a solder bath of a desired composition, and reeling out the wire at a constant rate.

In the solar cell string of the present invention, the above-described solar cell with a silver paste electrode coated with lead-free solder is interconnected with the solar cell interconnector. By interconnecting the solar cell with the solar cell interconnector by the silver paste electrode described above, the adherence between the interconnector and the solar cell is high even in an environmental condition of a great change in temperature and/or humidity. Thus, a solar cell string of high reliability can be provided.

The solar cell string of the present invention can be fabricated as set forth below. Referring to FIG. 2, an interconnector 12 coated with lead-free solder and cut to a predetermined length is brought into contact with a main electrode 11 coated with lead-free solder at the light receiving side of the solar cell. The solar cell and the interconnector are together exposed to a blow of hot air at approximately 400° C., whereby respective solder is melted, and then cooled to be solidified. Accordingly, the interconnector and the solar cell are integrated with each other. Then, the solar cell is inverted or the like such that a similar process can be carried out on the back surface electrode of the solar cell. Thus, a solar cell string of the present invention can be fabricated.

A solar cell module of the present invention incorporates the above-described string. By incorporating the above-described string, a module of high reliability, exhibiting high adherence between the interconnector and the solar cell even under an environmental condition of a great change in temperature and/or humidity can be produced. The module of the present invention is not restricted to any particular configuration as long as the above-described string is incorporated. For example, a super straight scheme is preferably employed, wherein the string is enclosed by a transparent filler and a back surface coat with a transparent substrate such as a glass plate at the light receiving side of the solar cell. As to the transparent filler, PVB (polyvinyl butyrol) exhibiting low light transmittance, EVA (ethylene vinyl acetate) superior in moisture resistance, and the like may be employed.

As to a flux used in applying a solder coat on the silver paste electrode, a flux material composed of only a polyalkylglycol-type resin and a solvent, absent of an activator, can be used. Namely, a flux containing a resin, a solvent, and a resin stabilizer can be used. The silver paste electrode is washed in a flux containing a resin, a solvent, and a resin stabilizer. Then, the silver paste electrode is coated with lead-free solder.

As to the lead-free solder, Sn—Bi—Ag based solder or Sn—Ag based solder can be used. The Sn—Bi—Ag based solder or Sn—Ag based solder has a melting point lower than that of Sn solder. In the present specification, Sn—Bi—Ag based solder contains at least 0.1 mass % Ag. The Sn—Ag based solder includes at least 0.1 mass % Ag.

In the Sn—Bi—Ag based solder, the amount of Bi contained is preferably 3 to 89 mass %, further preferably 35 to 60 mass %. Such ranges of the amount of Bi are selected as set forth below. In order to conduct a solder dip step without any problems, it is desirable to carry out the dipping step at approximately 195° C., which is the current temperature of a dipping process. From the standpoint of property, reliability, and the like, dipping must be carried out at a temperature lower than 225° C. that is the upper limit in practical usage. A composition having a melting point of 225° C. at most corresponds to 5 to 88 mass % Bi when the amount of Ag contained is 0.1 mass %, and to 3-89 mass % Bi when the amount of Ag contained is 1.3 mass %. A composition having a melting point of 195° C. at most corresponds to 27 to 79 mass % Bi when the amount of Ag contained is 0.1 mass %, and to 35-60 mass % Bi when the amount of Ag contained is 1.3 mass % Ag. Thus, the amount of Bi contained is preferably 3-89 mass %, further preferably 35 to 60 mass % for Sn—Bi—Ag based solder.

In the case of Sn—Ag based solder, a composition having a melting point of 225° C. at most contains 3.5 to 4.5 mass % Ag. There is no composition of this Sn—Ag based solder that has a melting point of 195° C. and below. Thus, the amount of Ag contained is preferably 3.5 to 4.5 mass % for Sn—Ag based solder.

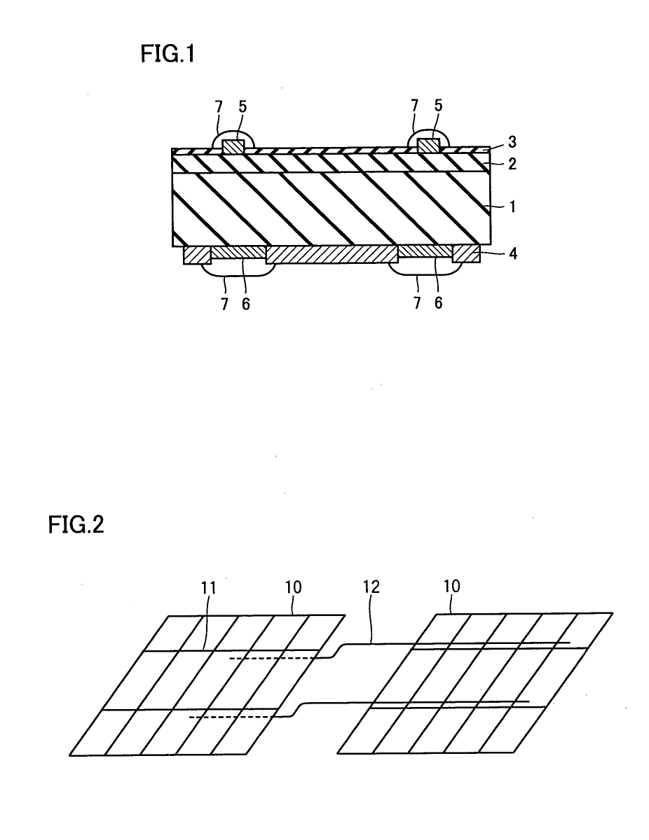

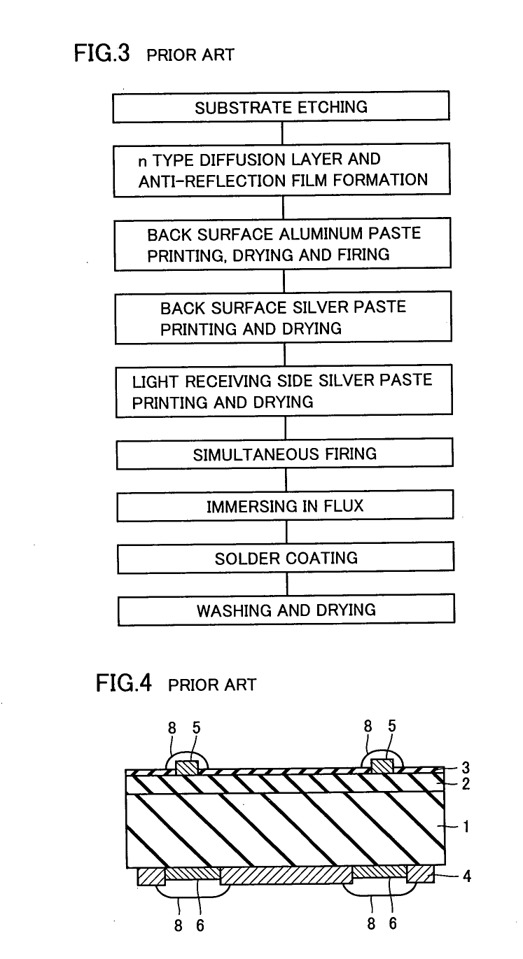

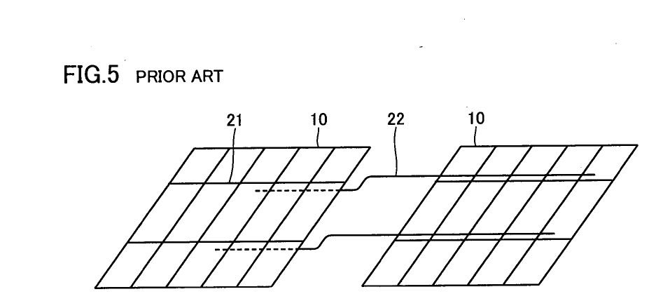

Examples of the present invention will be described with reference to the schematic sectional view of a solar cell of the present invention shown in FIG. 1. Referring to FIG. 1, on a texture-etched p type silicon substrate 1 having a thickness of 330 μm and an area of 125 mm by 125 mm, an n type diffusion layer 2 having a surface resistance of 50 Ω/□ by thermal diffusion of phosphorus (P) at 900° C. was formed. Then, a silicon nitride film of 60 nm was formed thereon by plasma CVD (Chemical Vapor Deposition) as an anti-reflection film 3. Commercially available aluminum paste was applied by screen-printing on a major part of the back surface (excluding the silver paste electrode formation region), dried at approximately 150° C., and then fired in air at 700° C. to form back surface aluminum electrode 4.

Also, a silver paste firing step was conducted on p type silicon substrate 1 having n type diffusion layer 2 and anti-reflection film 3 at one side surface (light receiving side) and back surface electrode 4 at a major part of the other side surface (back side) to form silver paste electrodes 5 and 6.

The silver paste electrode formation step through silver paste firing was carried out in accordance with the following procedure. Silver paste with the basic composition of those shown in Table 1 set forth below was applied by screen-printing to a predetermined thickness at a predetermined region (the region where back surface aluminum electrode 4 is not formed) at the back surface of p type silicon substrate 1. This silver paste was dried for approximately 4 minutes at 150° C. Then, a pattern of silver paste was printed at the light receiving side. The silver paste was dried, and then fired for two minutes in an oxidizing atmosphere under the temperature of 600° C., whereby silver paste electrodes 5 and 6 were formed at the front side and the back side.

TABLE 1

| Components | Rate (mass %) |
|---|---|
| Powdery silver | 79.41 |
| Powdery glass | 2.00 |
| Organic vehicle | 7.54 |
| Phosphorous pentoxide | 0.10 |
| Organic solvent | 10.945 |
| Illidium chloride | 0.005 |

The solar cell with the silver paste electrode formed was immersed in a flux of the composition shown in Table 2 set forth below. Then, the solar cell was dried by hot air, and immersed in a solder bath of the composition of Sn-40Bi-1.25 Ag, which is a composition of the Sn—Bi—Ag based lead-free solder shown in Table 3 set forth below, whereby lead-free solder layer 7 was formed. To improve the wettability, a small amount of phosphorus, antimony, or gallium can be contained in the solder. Then, rinsing was conducted in pure water and hot pure water for a total of five minutes. The solar cell was dried to result in a completed solar cell. Although Table 3 shows a Sn—Bi—Ag based solder and Sn—Ag based solder as the lead-free solder, either thereof can be used to cover the electrode.

TABLE 2

| Component | Rate (mass %) |
|---|---|
| Polyalkylglycol-type resin | 49.9 |
| Alcohol | 49.9 |
| Amine-type stabilizer | 0.2 |

TABLE 3

| Lead-free solder | Dip temperature (° C.) |
|---|---|
| Sn—Bi—Ag based | 193 |
| Sn—Ag based | 222 |

The connection of the solar cell described above with an interconnector coated with lead-free solder having the above-identified composition will be described hereinafter. An interconnector cut to a desired length was brought into contact with the silver paste electrode coated with lead-free solder of the solar cell. The interconnector and the solar cell were together subjected to a blow of hot air at approximately 400° C., whereby respective solder were melted and then cooled to be solidified. Thus, the interconnector and the solar cell were integrated with each other.

To evaluate the reliability of adherence between the solar cell and interconnector, a test piece having the silver paste electrode of such a solar cell connected to an interconnector was subjected to a temperature-humidity cycle test A-2 of JIS (Japanese Industrial Standard) C 8917 as an environmental condition of great change in temperature and/or humidity. The interconnector detachment rate was measured after the A-2 test was conducted for 25 cycles. JIS C 8917 corresponds to an environment testing method and endurance testing method for a solar cell module. In the present embodiment, a test piece having an interconnector connected to the silver paste electrode of a solar cell was employed.

“Interconnector detachment rate (%)” is the rate of the test points corresponding to detachment of the interconnector from the solar cell out of the test points of conducting the aforementioned temperature-humidity cycle test, expressed in percentage. Measurement was effected on ten test pieces, ten points for one test piece (total of 100 points) for every one test.

<Effect of Average Grain Size of Powdery Glass>

The relationship between the average grain size of powdery glass included in the silver paste and the interconnector detachment rate after the temperature-humidity cycle test is shown in Table 4 set forth below for Examples 1 and 2 of the present invention and Comparative Example 1. In Table 4, all the examples had the silver paste composition shown in Table 1, i.e., the amount of powdery glass contained was 2.0 mass %, and the average thickness of the silver paste electrode after firing was 10 μm.

TABLE 4

| | | Interconnector |
|---|---|---|
| | Average Grain Size | Detachment Rate After |
| | of Powdery Glass | Temperature-Humidity |
| | (μm) | Cycle Test (%) |
| Comparative | 20 | 100 |
| Example 1 | | |
| Example 1 | 11 | 50 |
| Example 2 | 5 | 0 |

As shown in Table 4, the interconnector detachment rate was improved to ½ by setting the average grain size of powdery glass to 11 μm from 20 μm. No interconnector detachment was detected when the average grain size of powdery glass was set to 5 μm. It is therefore appreciated that the interconnector detachment rate can be lowered by reducing the average grain size of powdery glass. Accordingly, the reliability of a solar cell can be improved.

<Effect of Amount of Powdery Glass>

The relationship between the amount of powdery glass (mass %) included in the silver paste and the interconnector detachment rate after the temperature-humidity cycle test is shown in Table 5 set forth below for Examples 1, 3, 4, and 5. The mass ratio of the composition of silver paste in the examples shown in Table 5 was similar to that shown in Table 1 with the exception of powdery glass. The examples were prepared with the amount of powdery glass respectively altered to 2.0 mass %, 2.8 mass %, 3.0 mass % and 4.0 mass %. All the examples in Table 5 used powdery glass having the average grain size of 11 μm, and the average thickness of the silver paste electrode after firing was 10 μm.

TABLE 5

| | | Interconnector |
|---|---|---|
| | | Detachment Rate After |
| | Amount of Powdery | Temperature-Humidity |
| | Glass (mass %) | Cycle Test (%) |
| Example 1 | 2 | 50 |
| Example 3 | 2.8 | 3 |
| Example 4 | 3 | 0 |
| Example 5 | 4 | 0 |

As shown in Table 5, the interconnector detachment rate can be lowered significantly by setting the amount of powdery glass to at least 2.8 mass %. Accordingly, the reliability of the solar cell can be improved significantly.

<Effect of Average Thickness of Silver Paste Electrode After Firing>

The relationship between the average thickness of a silver paste electrode after firing and the interconnector detachment rate after the temperature-humidity cycle test is shown in Table 6 set forth below for Examples 1, 6 and 7. All the examples in Table 6 used powdery glass having the average grain size of 11 μm, and the amount of powdery glass contained in the composition of the silver paste was 2.0 mass %, as shown in Table 1.

TABLE 6

| | Average Thickness | Interconnector |
|---|---|---|
| | of Silver Paste | Detachment Rate After |
| | Electrode after | Temperature-Humidity |
| | Firing (μm) | Cycle Test (%) |
| Example 1 | 10 | 50 |
| Example 6 | 15 | 20 |
| Example 7 | 20 | 0 |

As shown in Table 6, the interconnector detachment rate was improved to ½ by setting the average thickness of the silver paste electrode after firing to 15 μm from 10 μm. No detachment of the interconnector was detected by setting the average thickness to 20 μm. It is therefore appreciated that the interconnector detachment rate can be lowered by increasing the average thickness of the silver paste electrode after firing. Thus, the reliability of a solar cell can be improved.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A solar cell having a silver paste electrode coated with lead-free solder, wherein said silver paste electrode is formed by firing silver paste, and powdery glass included in said silver paste has an average grain size of 11 μm at most.

2. A solar cell having a silver paste electrode coated with lead-free solder, wherein said silver paste electrode is formed by firing silver paste, and an amount of powdery glass included in said silver paste is 2.8 to 10.0 mass %.

3. A solar cell having a silver paste electrode coated with lead-free solder, wherein said silver paste electrode after firing has an average thickness of at least 15 μm.

4. A fabrication method of a solar cell comprising the steps of printing silver paste at a partial region at a light receiving side of an anti-reflection film and at a partial region at a back side of a p type silicon substrate, firing said silver paste to form a silver paste electrode, and coating said silver paste electrode with lead-free solder, wherein powdery glass sifted though a sieve having an opening diameter of 73 μm at most is used as said powdery glass included in said silver paste.

5. A fabrication method of a solar cell comprising the steps of printing silver paste at a partial region at a light receiving side of an anti-reflection film and at a partial region at a back side of a p type silicon substrate, firing said silver paste to form a silver paste electrode, and coating said silver paste electrode with lead-free solder, wherein the step of printing silver paste includes applying silver paste at least two times.

6. A fabrication method of a solar cell comprising the steps of printing silver paste at a partial region at a light receiving side of an anti-reflection film and at a partial region at a back side of a p type silicon substrate, firing said silver paste to form a silver paste electrode, and coating said silver paste electrode with lead-free solder, wherein the step of printing silver paste includes applying silver paste using a mask having a thickness of three times a wire diameter.

7. An interconnector for a solar cell, said interconnector coated with lead-free solder, and said interconnector connected to a silver paste electrode of a solar cell by lead-free solder.

8. A solar cell string interconnecting a solar cell having a silver paste electrode coated with lead-free solder with an interconnector for a solar cell, wherein said paste electrode is formed by firing silver paste, and powdery glass included in said silver paste has an average grain size of 11 μm at most.

9. A solar cell module incorporated with a string interconnecting a solar cell having a silver paste electrode coated with lead-free solder with an interconnector for a solar cell, wherein said paste electrode is formed by firing silver paste, and powdery glass included in said silver paste has an average grain size of 11 μm at most.

10. A solar cell module incorporated with a string interconnecting a solar cell having a silver paste electrode coated with lead-free solder with an interconnector for a solar cell, wherein said paste electrode is formed by firing silver paste, and an amount of powdery glass included in said silver paste is 2.8 to 10.0 mass %.

11. A solar cell module incorporated with a string interconnecting a solar cell having a silver paste electrode coated with lead-free solder with an interconnector for a solar cell, wherein said silver paste electrode after firing has an average thickness of at least 15 μm.
